(19) United States
(12) Patent Application Publication
(10) Pub. No.: US 2023/0123051 A1
(43) Pub. Date: Apr. 20, 2023

(54) ELECTRICITY-GENERATING COATING FOR A SURFACE OF A CARGO CARRYING VEHICLE TO PRODUCE ELECTRICITY

(71) Applicant: SolarWindow Technologies, Inc., Scottsdale, AZ (US)

(72) Inventors: John A. Conklin, Apalachin, NY (US); Patrick T. Sargent, Canton, GA (US); James B. Whitaker, Denver, CO (US)

(21) Appl. No.: 18/064,143

(22) Filed: Dec. 9, 2022

Related U.S. Application Data
(63) Continuation of application No. PCT/US2021/037112, filed on Jun. 11, 2021.
Application No. PCT/US2021/037112 is a continuation of application No. 16/900,853, filed on Jun. 12, 2020, now abandoned.

(51) Int. Cl. H10K 30/80; H10K 71/10

(52) U.S. Cl. CPC H01L 51/44; H01L 51/0002

(57) ABSTRACT

An electricity-generating coating is provided for a surface of a cargo carrying vehicle. The electricity-generating coating includes a conformal organic photovoltaic device configured to be applied and conformed to the surface of the cargo carrying vehicle and configured to supply power for one or more electronic or electrical components or systems at least one of on-board or off-board the cargo carrying vehicle.

### FIELD OF THE INVENTION

The present invention s directed to an electricity-generating coating for surfaces of a cargo carrying vehicle, and an element for a cargo carrying vehicle, in which the component includes an electricity-generating coating, to provide electricity for components, on-board systems, off-board systems, emergency use, and/or vehicle-to-grid power transfer systems.

### BACKGROUND OF THE INVENTION

A conventional cargo carrying vehicle, such as a semi-tractor-trailer truck, military transport, or the like, for transporting cargo/freight on or off a roadway, can include a variety of electrical systems and components that draw power during operation of the vehicle as well as during instances in which the vehicle is idle, For example, a cargo carrying vehicle may include a tractor having a cab or a sleeper cab with one or more electronic components and systems such as audio/video systems, computer systems, Wi-Fi systems, radio for person-to-person or person-to-base, etc., as well as other electrical systems such as interior and exterior lighting, heating and air condition units, etc. In some examples, a cargo carrying vehicle also may include a trailer having one or more electrical components or systems such as interior and exterior lighting, heating and air condition units, etc.

### SUMMARY OF THE INVENTION

The present invention recognizes that the various electronic/electrical components and systems of a cargo carrying vehicle, such as a semi-tractor-trailer truck, military transport, or the like, having for example a tractor and/or a trailer, can draw power from one or more batteries or an alternator of the vehicle during operation of the vehicle or idle times that may affect performance of the vehicle, such as fuel efficiency, reliability, etc.

These problems and others are addressed by the present invention, an exemplary embodiment of which comprises an electricity-generating coating for a surface of a cargo carrying vehicle, the electricity-generating coating comprising a conformal organic photovoltaic device configured to be applied and conformed to the surface of the cargo carrying vehicle and configured to supply power for one or more electronic or electrical components or systems at least one of on-board and off-board the cargo carrying vehicle. In this way, the present invention can provide power for various electronic/electrical components and systems on-board or off-board of a cargo carrying vehicle, such as a tractor and/or a trailer, such as one or more batteries of the vehicle during operation of the vehicle or during idle times, among other things, thereby improving performance of the vehicle, such as improving fuel efficiency, reliability, etc. of a cargo carrying vehicle or providing power to off-board components and/or systems, such as a building power system or power grid.

For purposes on this invention, a “cargo carrying vehicle” is defined as a vehicle capable of carrying or transporting goods, materials, cargo, equipment, freight, people, troops, and/or other vehicles, etc., among, other items, from one location to another.

Such a cargo carrying vehicle is not limited to any particular vehicle and can include a vehicle propelled by one or more motive means, such as a motorized vehicle (e.g., fossil fuel powered vehicle), an electric vehicle, a magnetically propelled vehicle, a hydrogen-powered vehicle, a wind-powered vehicle, a propeller, turbine, or jet engine powered vehicle, and/or an ambulatory powered vehicle, etc., among other types of vehicles.

Such a cargo carrying vehicle can include a vehicle configured for operation on various roadway surfaces, off-road operation, water operation, air operation, rail operation, stationary or floating platform operation, etc.

Such a cargo carrying vehicle can include a vehicle configured for military use or civilian use, including for example commercial use, private use, municipal or government use, use by armed services, law enforcement, or other organizations, etc.

For example, a cargo carrying vehicle can include a truck such as a semi-tractor-trailer truck having a tractor and optionally one or more trailers, a truck with an attached box or bed, etc. Such a tractor or truck can include a cab or a sleeper cab with one or more electronic components and systems such as audio/video systems, computer systems, Wi-Fi systems, radio for person-to-person or person-to-base, etc., as well as other electrical systems such as interior and exterior lighting, heating and air condition units, etc. In examples in which the cargo carrying vehicle includes a trailer or a truck with an attached box or bed, etc., the trailer or attached box or bed can include one or more electrical components or systems such as interior and exterior lighting, heating and air condition units, etc.

In other examples, a cargo carrying vehicle can include other vehicles or transports.

For example, a cargo carrying vehicle can include construction, mining, or building equipment, such as mining, drilling, excavating, and/or earthmoving equipment, lifting equipment for lifting and/or moving, etc.

In other examples, a cargo carrying vehicle can include a railway vehicle such as a monorail or a train including cargo, passenger, and/or commuter railway vehicles, etc. such as motorized railway vehicles, electric railway vehicles, magnetic railway vehicles, etc.

In still other examples, a cargo carrying vehicle can include a water vessel including a cargo, passenger, and/or commute water vessel, etc. configured for military use or civilian use, including for example commercial use, private use, municipal or government use, use by armed services, coast guard, law enforcement, or other organizations, etc., including a motorized water vessel, an electric water vessel, and/or a wind-powered vessel, etc., such as a yacht, fishing boat, recreation watercraft, sailboat, armed services watercraft, lifesaving/lifeguard watercraft, etc. among other things.

In yet other examples, a cargo carrying vehicle can include other vehicles such as so-called people movers, for example, for use in airports, amusement parks, etc.

Such examples of a cargo carrying vehicle can include one or more electronic components and systems such as audio/video systems, computer systems, Wi-Fi systems, radio for person-to-person or person-to-base, etc., as well as other electrical systems such as interior and exterior lighting, heating and air condition units, etc. Additionally or alternatively, such a trailer, attached box, bed, and/or bucket, etc. can include one or more electrical components or systems such as interior and exterior lighting, heating and air condition units, etc.

The present invention recognizes that a cargo carrying vehicle, such as a semi-tractor-trailer truck, can include a tractor having a cab or a sleeper cab with a variety of exterior surfaces configured to improve aerodynamic characteristics of the vehicle, provide sufficient space within the vehicle for one or more vehicle operators to rest or sleep during idle times, etc. Additionally, the tractor can include a variety of exterior surfaces such as non-transparent surfaces formed from steel, aluminum, plastic, fiberglass, thermoplastic, etc. as well as a variety of transparent surfaces such as one or more cab or sleeper side windows, sky lights, moon roofs, etc. In some examples, such cargo carrying vehicle also may include a trailer having a variety of surfaces configured to provide sufficient space within the trailer for securing cargo/freight, improving aerodynamic characteristics of the trailer, etc. Aside from, for example, providing aesthetics, improving aerodynamic characteristics, or being used for signage on the vehicle, the various exterior surfaces of the tractor and/or trailer generally are passive surfaces that do not contribute to the operation of components of the vehicle, and particularly, to operation of electronic or electrical components and systems of the tractor and/or trailer. Due to the nature and size of such a cargo carrying vehicle, the surface area of the various exterior surfaces of the tractor and/or trailer can be considerably large and may be directly or indirectly exposed to natural sunlight during operation of the vehicle as well as during idle times.

The present invention further recognizes that the arrangement and configuration as well as the large surface area of the various exterior surfaces of the vehicle may be configured to provide functionality to the vehicle by adhering or covering one or more of the exterior surfaces with one or more photovoltaic devices (PV devices), which can provide electricity, for example, to help power one or more electronic or electrical components and systems on-board the vehicle. The present invention recognizes that conventional inorganic PV devices make little sense for cargo carrying vehicle for a number of reasons, such as excessive weight and potentially bulky structures that could increase wind resistance, both of which would reduce fuel efficiency of the cargo carrying vehicle.

For purposes of the invention, an “electricity-generating coating” can include, for example, organic photovoltaic (OPV), Perovskites, dye-sensitized solar cells, or amorphous silica, among other things.

The present invention recognizes that organic PV (OPV), Perovskites, dye-sensitized solar cells, or amorphous silica devices (electricity-generating coating) can provide a number of features that are particularly suitable for a cargo carrying vehicle, including low specific weight (W/g), flexibility, and thickness of thin film electricity-generating coating devices. The very low specific weight of electricity-generating coating devices, as compared to other PV technologies, may minimize an impact on fuel efficiency of the cargo carrying vehicle. Additionally, the present invention recognizes that an electricity-generating coating device can be flexible, which can enable application methods for non-planar surfaces, such as curved aerodynamic exterior surfaces of the cab, sleeper cab, trailer, and/or other components thereon. Furthermore, the present invention recognizes that the tunable nature of the absorption in electricity-generating coating materials can allow for customized power production, surface appearances, and opacity.

An exemplary embodiment of the invention is directed to an electricity-generating coating for a surface of a cargo carrying vehicle, the electricity-generating coating comprising a conformal organic photovoltaic device configured to be applied and conformed to the surface of the cargo carrying vehicle and configured to supply power for one or more electronic or electrical components or systems on-board and/or off-board the cargo carrying vehicle.

In an exemplary embodiment, the conformal organic photovoltaic device can be configured to be applied and conformed to the surface of the cargo carrying vehicle by coating the conformal organic photovoltaic device onto the surface of the cargo carrying vehicle.

For example, the conformal organic photovoltaic device can be coated directly onto the surface of the cargo carrying vehicle. The conformal organic photovoltaic device can be coated directly onto the surface of the cargo carrying vehicle such that a topography of the conformal organic photovoltaic device conforms (e.g., substantially conforms) to a topography of the surface of the cargo carrying vehicle. More particularly, the conformal organic photovoltaic device can be coated directly onto the surface of the cargo carrying vehicle without any space or entrapped air being present between the conformal organic photovoltaic device and the surface of the cargo carrying vehicle such that the topography of the conformal organic photovoltaic device directly conforms exactly conforms) to the topography of the surface of the cargo carrying vehicle. In some example embodiments, the surfaces can be coated via one or more of a number of techniques, such as spray, curtain, slot-die, gravure, etc. depending on the curvature of the surface being coated, the type of material being coated, etc. In some examples, a spray and curtain coating can be utilized for coating one or more curved surfaces, while a slot-die and gravure coating can be utilized for coating one or more planar surfaces.

In another exemplary embodiment, the electricity-generating coating can further comprise a pressure-sensitive adhesive on the conformal organic photovoltaic device. The conformal organic photovoltaic device can be configured to be applied and conformed to the surface of the cargo carrying vehicle by adhering and conforming the pressure-sensitive adhesive of the conformal organic photovoltaic device onto the surface of the cargo carrying vehicle.

The pressure-sensitive adhesive of the conformal organic photovoltaic device can be configured to be adhered and conformed directly onto the surface of the cargo carrying vehicle. The pressure-sensitive adhesive of the conformal organic photovoltaic device can be configured to be adhered and conformed directly onto the surface of the cargo carrying vehicle such that a topography of the conformal organic photovoltaic device conforms to a topography of the surface of the cargo carrying vehicle. In some examples, the pressure-sensitive adhesive of the conformal organic photovoltaic device can be configured to be adhered and conformed directly onto the surface of the cargo carrying vehicle without any space or entrapped air being present between the pressure-sensitive adhesive of the conformal organic photovoltaic device and the surface of the cargo carrying vehicle such that the topography of the conformal organic photovoltaic device directly conforms to the topography of the surface of the cargo carrying vehicle.

A topography of the surface of the cargo carrying vehicle includes at least one planar surface, at least one curved surface, or a combination of at least one planar surface and at least one curved surface.

The surface of the cargo carrying vehicle can be a non-transparent surface. In other examples, the surface of the cargo carrying vehicle can be one of a transparent surface and a semi-transparent surface. The conformal organic photovoltaic device can he semitransparent such that light is capable of passing through the conformal organic photovoltaic device and the pressure-sensitive adhesive of the electricity-generating coating from either side.

If the surface of the cargo carrying vehicle is one of a transparent surface and a semi-transparent surface, then the conformal organic photovoltaic device can be semitransparent and the pressure-sensitive adhesive can be one of semitransparent and transparent such that light is capable of passing through the conformal organic photovoltaic device and the pressure-sensitive adhesive of the electricity-generating coating from either side.

In other examples, in which the surface of the cargo carrying vehicle is not transparent surface or semi-transparent surface, the conformal organic photovoltaic device can be semitransparent and/or the pressure-sensitive adhesive can be one of semitransparent and transparent such that light is capable of passing through the conformal organic photovoltaic device and the pressure-sensitive adhesive of the electricity-generating coating to permit viewing of the surface of the cargo carrying vehicle. In this way, the original surface appearance and characteristics (e.g., color, texture, contours, topography, graphics, etc.) of the cargo carrying vehicle can be visible, or at least partially visible, through the conformal organic photovoltaic device and/or the pressure-sensitive adhesive.

In an example, the conformal organic photovoltaic device can be flexible (e.g., a flexible coating) or rigid (e.g., a rigid coating) and/or the pressure-sensitive adhesive can be flexible (e.g., a flexible adhesive) or rigid (e.g., a rigid adhesive).

The conformal organic photovoltaic device can be configured for a surface of the cargo carrying vehicle that is an exterior surface of the cargo carrying vehicle, a component of the cargo carrying vehicle, and/or an attachment of the cargo carrying vehicle.

The conformal organic photovoltaic device can be configured for a surface of the cargo carrying vehicle that is an interior surface of the cargo carrying vehicle, a component of the cargo carrying vehicle, and/or an attachment of the cargo carrying vehicle, such as an interior of a window unit, glass light, moonroof, etc.

According to the exemplary embodiments of the invention, an electricity-generating coating can be applied to surfaces or portions of surfaces, for example, as adhesive backed film or conformal coating. Such an electricity-generating coating can be applied and conformed to surfaces having a variety of topographies, such as planar surfaces, curved surfaces, or combinations thereof. For example, such an electricity-generating coating can be applied to cover or conform to a topography of all or a portion of a surface (e.g., an exterior surface) of a hood, roof, fender, etc., rather than being simply mounted onto a substantially flat surface as a part of a mount-on assembly, as compared to conventional PV panels. Also, by conforming such an electricity-generating coating to a surface of the cargo carrying vehicle, or providing an electricity-generating coating within a window unit of the cargo carrying vehicle, the present invention can reduce or minimize a consideration, concern, and/or risk of aerodynamic affects, such as reducing or minimizing a risk of creating drag, reducing or minimizing a risk of PV panel being jarred or pulled loose by wind, etc.

According to the exemplary embodiments, a leading edge of the exemplary electricity-generating coating can be more readily and easily positioned on a surface, or concealed behind another surface, or concealed within a window unit, to minimize exposure to wind during operation of the cargo carrying vehicle. In stark contrast, conventional PV panels commonly must be positioned on broad, substantially flat areas or surfaces, which typically means the leading edges of such panels will be directly exposed to wind during operation of the vehicle or will require an additional component, such as a wind deflector, to direct wind over the surface of the conventional PV panel.

In the exemplary embodiments, the electricity-generating coating can be applied as a completed device onto an exterior surface of the vehicle using a thin, flexible substrate with pressure-sensitive adhesives. In this way, an exemplary electricity-generating coating suitable for the present invention can be fabricated in a high-throughput manner via roll-to-roll manufacturing onto a flexible planar substrate (with backing material, if necessary) that can then be applied to either or both of planar exterior surfaces of the vehicle and curved exterior surfaces of the vehicle. The exemplary electricity-generating coating device can then be wired into one or more electronic or electrical components or systems of the vehicle, for example, via small connection terminals in, or below, the surface, and any necessary power electronics, such as inverters, batteries, and the like can be located inside the vehicle.

In some examples, a top surface (exterior facing surface) of the exemplary electricity-generating coating device can include a protective hard clear-coat (e.g., a clear epoxy, ceramic coating, or impact resistant transparent oxide, among other things) to protect the electricity-generating coating from physical damage and environmental stress, as well as from moisture and oxygen ingress, thereby improving durability which may provide a superior lifetime of the device compared with conventional PV or electricity-generating coating devices. In these ways, the various and abundant surface area of the exterior surfaces of the vehicle, including one or more surfaces of the tractor and/or trailer, can be configured as electricity-generating surfaces to provide power to one or more electronic and/or electrical components and/or systems of the vehicle, while at the same time minimizing the addition of weight to the vehicle and resulting in a smooth, hard, low-drag surface to minimize any reduction in fuel efficiency of the vehicle. Furthermore, by selecting appropriate electricity-generating coating material absorption properties, the surface visual effect of the vehicle can be matched to the vehicle design profile, while generating power for the vehicle.

Another exemplary embodiment of the invention comprises an electricity-generating coating device comprising one or more cells connected in series and/or parallel. The exemplary electricity-generating coating device can be fabricated directly on an exterior surface or exterior facing surface of the vehicle or a component of the vehicle before, during, or after assembly of the vehicle.

In an exemplary method, first, an insulating layer can be deposited to allow isolation of the individual cells from each other and from the surface(s) of the vehicle (e.g., metal surfaces), to prevent electrification of a part of the body of the vehicle (e.g., a part or the entire surface of the cab, sleeper cab, trailer, etc.). Second, additional layers of the electricity-generating coating device can be deposited in typical fashion via one or more appropriate coating and patterning techniques, as would be understood by one of ordinary skill in the art of electricity-generating coating, to produce a completed device directly on a surface of the vehicle. In these examples, the wiring of the system can be accomplished via small terminals on, or below, the surface of the vehicle, and a hard top clear-coat (e.g., epoxy, ceramic coating, or impact resistant transparent oxide) can be applied to provide a hard, low-drag surface that is capable of protecting the electricity-generating coating device. Such completed electricity-generating coating-coated surfaces or surface panels can then be assembled or mounted directly on the body or chassis of the vehicle, and correspondingly provided with suitable wiring and/or electrical connections and any necessary power electronics, such as inverters and batteries, placed inside the vehicle.

In this way, the exemplary embodiments can provide an electricity-generating coating configured to generate power for various electronic/electrical components and systems of a cargo carrying vehicle, c such as a tractor and/or a trailer, such as one or more batteries of the vehicle during operation of the vehicle or during idle times of the vehicle, thereby improving performance of the vehicle, such as improving fuel efficiency, reliability, etc. of a cargo carrying vehicle.

In other exemplary embodiments, an electricity-generating coating can be configured as novel photovoltaic window technology, based upon OPV, Perovskites, dye-sensitized solar cells, or amorphous silica (electricity-generating coating) which can provide the ability to generate power while retaining a high level of visible light transmission (VLT) in one or both direction for a window application.

Very few conventional PV technologies can be made inherently semi-transparent, and thus compatible with window technologies, and the few that can generally have very low VLT and poor aesthetics. For example, semi-transparent amorphous silicon is generally red in appearance, with low VLT, which would be prohibitive for a window of a cargo carrying vehicle. electricity-generating coating has a number of other inherent benefits for cargo carrying vehicle including low specific weight (W/g), flexibility, and thickness of the thin films. An important feature is the very low specific weight of electricity-generating coating, as compared to other PV technologies, and an inherent flexibility that allows unique application to non-planar surfaces, such as curved window surfaces of a cargo carrying vehicle Furthermore, the tunable nature of the absorption in electricity-generating coating materials allows customized appearance and performance in semi-transparent window applications, which would allow performance to be optimized for different windows of a cargo carrying vehicle.

The coating can be applied to either the exterior or interior of the window of the cargo carrying vehicle, depending on the desired properties, but the interior coating likely has significant benefits, including increased protection of the electricity-generating coating module and easier electrical connections. In this embodiment, the electricity-generating coating device can either be applied as a completed device onto the window surface using a thin, flexible substrate with pressure-sensitive adhesives, or the electricity-generating coating device can be fabricated directly on the window through standard coating (e.g. spray, slot-die, curtain, gravure, etc.) and processing (e.g., laser scribing) techniques, as known to those skilled in the art of electricity-generating coating. The electricity-generating coating device can provide electricity to help power electronic or electrical components and systems of a cargo carrying vehicle, while still retaining a high degree of VLT to ensure good visibility. Furthermore, the absorption properties of the electricity-generating coating module can be selected to optimize the visual transmission properties of the window, while still providing power.

As explained, the conformal organic photovoltaic device can be configured to supply power for one or more electronic or electrical components or systems or the cargo carrying vehicle.

For example, a cargo carrying vehicle can include one or more electronic components and systems such as audio/video systems, computer systems, Wi-Fi systems, radio for person-to-person or person-to-base, etc., as well as other electrical systems such as interior and exterior lighting, heating and air condition units, etc. Additionally or alternatively, such a trailer, attached box, bed, and/or bucket, etc. can include one or more electrical components or systems such as interior and exterior lighting, heating and air condition units, etc. More particularly, for example, a cargo carrying vehicle can include a truck such as a semi-tractor-trailer truck having a tractor and optionally one or more trailers, a truck with an attached box or bed, etc. Such a tractor or truck can include a cab or a sleeper cab with one or more electronic components and systems such as audio/video systems, computer systems, Wi-Fi systems, radio for person-to-person or person-to-base, etc., as well as other electrical systems such as interior and exterior lighting, heating and air condition units, etc. In examples in which the cargo carrying vehicle includes a trailer or a truck with an attached box or bed, etc., the trailer or attached box or bed can include one or more electrical components or systems such as interior and exterior lighting, heating and air condition units, etc.

Such an electricity generating coating can be configured on a part of a cargo carrying vehicle to be exposed to direct or indirect sunlight and/or artificial light for generating electricity for one or more on-board electronic components and systems such as audio/video systems, computer systems, Wi-Fi systems, radio for person-to-person or person-to-base, etc., as well as other electrical systems such as interior and exterior lighting, heating and air condition units, etc. of the cargo carrying vehicle or an attached accessory or other attached equipment (e.g., trailer) of the cargo carrying vehicle.

Additionally or alternatively, such an electricity generating coating can be configured on a part of a cargo carrying vehicle for generating electricity for one or more electronic components and systems outside of or separate from the cargo-carrying vehicle (e.g., off-board) such as being a part of a vehicle-to-grid power transfer system.

For example, the exemplary electricity-generating coating can enable a cargo carrying vehicle to be utilized as a possible solar generation platform, for example, for building integration, providing vehicle-to-grid power, providing emergency or temporary power (e.g., for life saving equipment, lighting, pumping, water supply equipment, etc.), among other things. The exemplary electricity-generating coating can be configured such that a cargo carrying vehicle can be utilized to generate power when the vehicle is in use (e.g., operation) and/or not in use (e.g., not in operation).

Other features and advantages of the present invention will become apparent to those skilled in the art upon review of the following detailed description and drawings.

### BRIEF DESCRIPTION OF THE DRAWINGS

These and other aspects and features of embodiments of the present invention will be better understood after a reading of the following detailed description, together with the attached drawings, wherein:

FIG. 1 is a schematic illustration of a cargo carrying vehicle having an electricity-generating coating according to exemplary embodiments of the invention;

FIG. 2 is a schematic illustration of a cargo carrying vehicle having an electricity-generating coating according to exemplary embodiments of the invention;

FIG. 3 is a schematic illustration of a cargo carrying vehicle having an electricity-generating coating according to exemplary embodiments of the invention;

FIG. 4 is a schematic illustration of a cargo carrying vehicle having an electricity-generating coating according to exemplary embodiments of the invention;

FIG. 5 is a schematic illustration of a cargo carrying vehicle having an electricity-generating coating according to exemplary embodiments of the invention;

FIG. 6 is a cross-sectional view of a pressure-sensitive adhesive-coated organic photovoltaic device, itself coated on a thin flexible substrate with a transfer release layer and rigid backing layer, which can be used to prepare planar and curved organic photovoltaic device-covered surface of a cargo carrying vehicle, according to an exemplary embodiment of this invention.

FIG. 7 is a cross-sectional view of an organic photovoltaic device coated onto a planar surface of a cargo carrying vehicle using the pressure-sensitive adhesive method according to an exemplary embodiment of the invention.

FIG. 8 is a cross-sectional view of an organic photovoltaic device coated onto a curved surface of a cargo carrying vehicle using the pressure-sensitive adhesive method according to an exemplary embodiment of the invention.

FIG. 9 is a cross-sectional view of an organic photovoltaic device coated directly onto a planar surface of a cargo carrying vehicle using conventional coating methods according to an exemplary embodiment of the invention.

FIG. 10 is a cross-sectional view of an organic photovoltaic device coated directly onto a curved surface of a cargo carrying vehicle using conventional coating methods according to an exemplary embodiment of the invention.

FIG. 11 is a cross-sectional view of a pressure-sensitive adhesive-coated, semitransparent organic photovoltaic device, itself coated on a thin flexible substrate with a transfer release layer and rigid backing layer, which can be used to prepare a planar and curved organic photovoltaic device-covered window of a cargo carrying vehicle, according to an exemplary embodiment of this invention.

FIG. 12 is a cross-sectional view of a semitransparent organic photovoltaic device coated onto a window of a cargo carrying vehicle using the pressure-sensitive adhesive method according to an exemplary embodiment of the invention.

FIG. 13 is a cross-sectional view of a semitransparent organic photovoltaic device coated directly onto a planar window windows of a cargo carrying vehicle using conventional coating methods according to an exemplary embodiment of the invention.

FIG. 14 is a cross-sectional view of a semitransparent organic photovoltaic device coated onto a curved window windows of a cargo carrying vehicle using the pressure-sensitive adhesive method according to an exemplary embodiment of the invention.

FIG. 15 is a cross-sectional view of a semitransparent organic photovoltaic device coated directly onto a curved window windows of a cargo carrying vehicle using conventional coating methods according to an exemplary embodiment of the invention.

### DETAILED DESCRIPTION OF THE EXEMPLARY EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

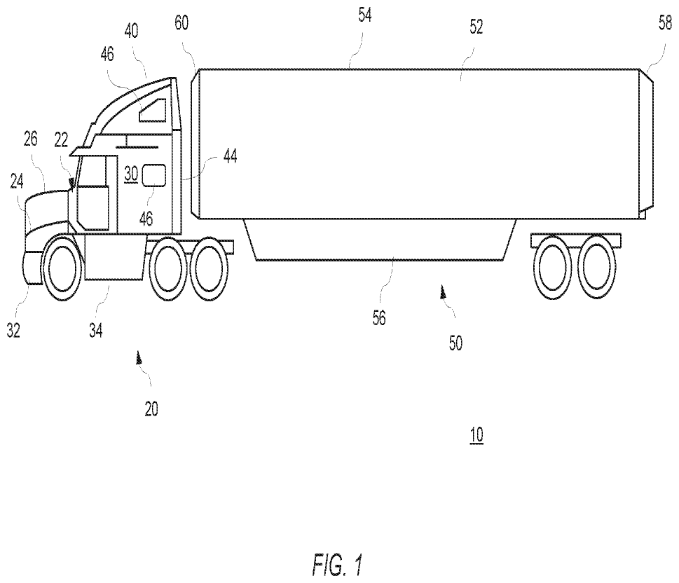

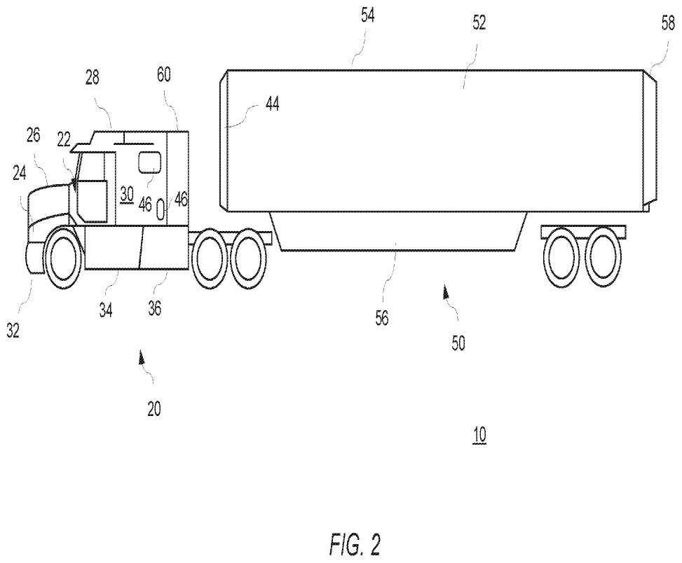

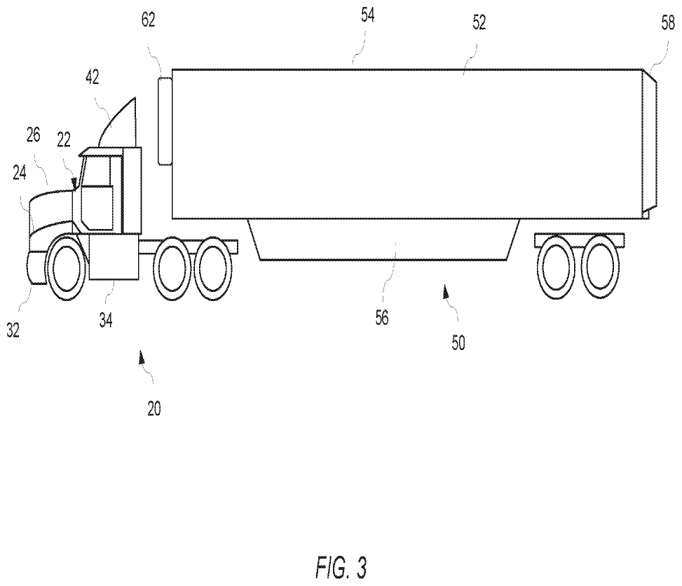

Referring now to the drawings, FIGS. 1-15 illustrate exemplary embodiments of electricity-generating coatings 100 for a cargo carrying vehicle 10. As explained in greater detail below, exemplary embodiments of the electricity-generating coating 100 can comprise a conformal organic photovoltaic device (e.g., a flexible conformal organic photovoltaic device), including one or more cells connected in series and/or parallel, wherein the conformal organic photovoltaic device is configured to be applied and conformed to a surface of the cargo carrying vehicle 10 and configured to supply power for one or more electronic or electrical components or systems on-board and/or off-board of the cargo carrying vehicle 10; and a pressure-sensitive adhesive on the flexible conformal organic photovoltaic device, the pressure-sensitive adhesive being flexible and configured to adhere and conform the flexible conformal organic photovoltaic device to the surface of the cargo carrying vehicle 10.

As explained, a “cargo carrying vehicle” is defined as a vehicle capable of carrying or transporting goods, materials, cargo, equipment, freight, people, troops, and/or other vehicles, etc., among other items, from one location to another, and is not limited to any particular vehicle. Such a cargo carrying vehicle can include a vehicle propelled by one or more motive means, such as a motorized vehicle (e.g., fossil fuel powered vehicle), an electric vehicle, a magnetically propelled vehicle, a hydrogen-powered vehicle, a wind-powered vehicle, a propeller, turbine, or jet engine powered vehicle, and/or an ambulatory powered vehicle, etc., among other types of vehicles, a vehicle configured for operation on various roadway surfaces, off-road operation, water operation, air operation, rail operation, stationary or floating platform operation, etc., a vehicle configured for military use or civilian use, including for example commercial use, private use, municipal or government use, use by armed services, law enforcement, or other organizations, etc. In other examples, a cargo carrying vehicle can include other vehicles or transports, such as construction, mining, or building equipment, such as mining, drilling, excavating, and/or earthmoving equipment, lifting equipment for lifting and/or moving, etc., a railway vehicle such as a monorail or a train including cargo, passenger, and/or commuter railway vehicles, etc. such as motorized railway vehicles, electric railway vehicles, magnetic railway vehicles, etc., a water vessel including a cargo, passenger, and/or commuter water vessel, etc. configured for military use or civilian use, including for example commercial use, private use, municipal or government use, use by armed services, coast guard, law enforcement, or other organizations, etc., including a motorized water vessel, an electric water vessel, and/or a wind-powered vessel, etc., such as a yacht, fishing boat, recreation watercraft, sailboat, armed services watercraft, lifesaving/lifeguard watercraft, etc. among other things, or other vehicles such as so-called people movers, for example, for use in airports, amusement parks etc.

With reference to FIGS. 1-5, an exemplary embodiment of a cargo carrying vehicle 10 will be described reference to a semi-tractor-trailer truck. One of ordinary skill in the art will recognize that the semi-tractor-trailer truck illustrated is for exemplary purposes, and is not intended to limit the invention to any particular example of, or part of, a cargo carrying vehicle.

As shown in FIGS. 1-5, a cargo carrying vehicle 10, such as a semi-tractor-trailer truck, can include a tractor 20 having a cab 22 or a sleeper cab 30 with a variety of exterior surfaces configured to improve aerodynamic characteristics of the vehicle 10

The tractor 20 can include a variety of exterior surfaces configured to improve aerodynamic characteristics of the vehicle 10, provide sufficient space within the vehicle 10 for one or more vehicle operators to rest or sleep during idle times, etc. The exterior surfaces can include non-transparent surfaces formed from steel, aluminum, plastic, fiberglass, thermoplastic, etc. The exterior surfaces of the cab 22 can include, for example, a front/grille, fenders 24, a hood/engine compartment cover 26, sides, rear, roof 28, doors, sleeper cab 30, bumper 32, mirrors, one or more side fairings, including fuel tank side fairings 34, storage side fairings 36, storage compartments 38, etc., a cab roof fairing 40, a cab roof wind deflector 42, and/or cab-mounted gap reducers 44, etc. The exterior surfaces of the cab 22 can include, for example, a variety of transparent surfaces such as one or more cab or sleeper side windows 46, sky lights, moon roofs, etc.

In an example in which the surface of the vehicle is a transparent surface, such as one or more cab or sleeper side windows 46, sky lights, moon roofs, etc., the conformal organic photovoltaic device can be semitransparent and a pressure-sensitive adhesive also can be one of semitransparent and transparent such that light is capable of passing through the conformal organic photovoltaic device and the pressure-sensitive adhesive of the electricity-generating coating from either side, thereby permitting visibility through the transparent surface of the vehicle 10 from within an interior of the vehicle 10 and/or from outside the vehicle 10.

With reference again to FIGS. 1-5, in some examples, a cargo carrying vehicle 10 also may include a trailer 50 having a variety of surfaces configured to provide sufficient space within the trailer 50 for securing cargo/freight, improving aerodynamic characteristics of the trailer, etc. For example, the trailer 50 can include one or more non-transparent surfaces such as front, side 52, rear, and/or roof 54 surfaces, side fairings 56, rear fairings or boat-tail 58, trailer-mounted gap reducers 60, and/or a trailer air conditioning unit(s) 62.

Some surfaces of the tractor 20 and trailer 50 can be planar, while other surfaces can be curved (e.g., non-planar in one or more dimensions).

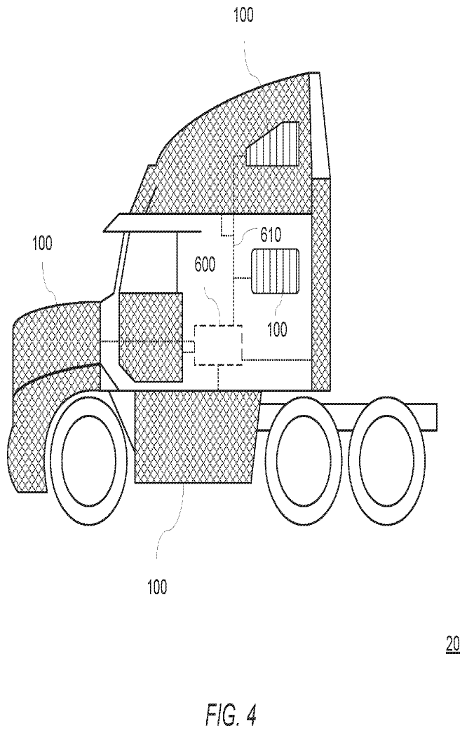

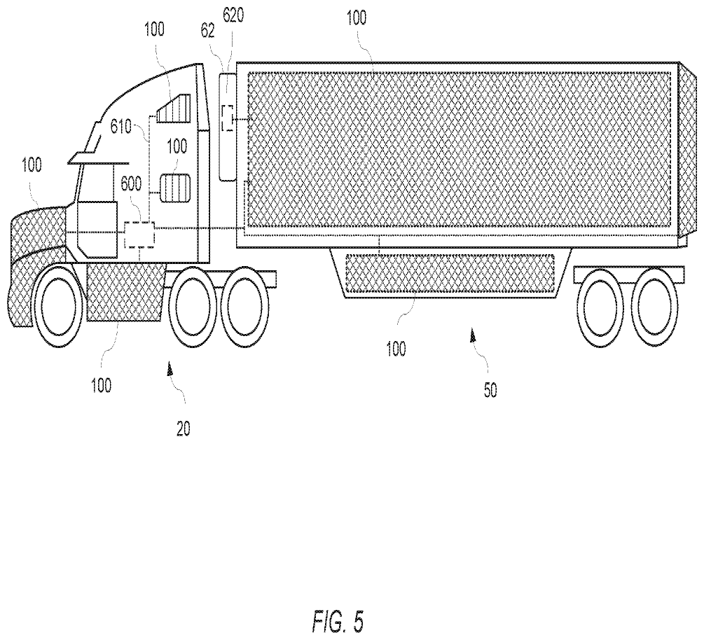

With reference to FIGS. 4 and 5, one or more electricity-generating coatings 100 can be applied and conformed (e.g., coated or adhered) to one or more surfaces of the vehicle 10. The one or more electricity-generating coatings 100 can comprise a conformal organic photovoltaic device (e.g., flexible coating or adhesive device), including one or tore cells connected in series and/or parallel, wherein the conformal organic photovoltaic device is configured to be applied and conformed (e.g., coated or adhered) to a surface of the cargo carrying vehicle 10 and configured to supply power for one or more electronic or electrical components or systems 600, for example, of the cargo carrying vehicle 10. The surfaces illustrated as having electricity-generating coatings 100 are for example purposes only and the embodiments are not limited to any particular surface or combination of surfaces.

As shown in FIG. 4, the tractor 20 can include one or more electricity-generating coatings 100 configured for providing power to one or more electronic or electrical components or systems 600 of the tractor 20. For example, one or more electricity-generating coatings 100 can be configured for charging (re-charging) and/or supplying power to one or more batteries of the tractor, for providing power for operation of one or more electronic components of the tractor, such as exterior lighting on the tractor (e.g. marker lights), interior lighting, audio/video unit(s), heating/air conditioning systems, electronics charging ports, etc. in the cab. One or more electrical connections 610 can be provided to connect the one or more electricity-generating coatings 100 configured for providing power to one or more electronic or electrical components or systems 600 of the tractor 20.

As shown in FIG. 4, the tractor 20 and/or the trailer 50 can include one or more electricity-generating coatings 100 configured for providing power to one or more electronic or electrical components or systems 600 of the tractor 20 and/or one or more electronic or electrical components or systems 620 of the trailer 50. For example, one or more electricity-generating coatings 100 can be configured for charging (re-charging) and/or supplying power to one or more batteries of the trailer 50, for providing power for operation of one or more electronic components of the trailer 50, such as exterior lighting on the trailer (e.g. marker lights), interior lighting within the cargo area of the trailer 50, heating/air conditioning systems 62 on the trailer 50, etc. One or more electrical connections 610 can be provided to connect the one or more electricity-generating coatings 100 configured for providing power to one or more electronic or electrical components or systems 600 of the tractor 20 and/or the trailer 50.

In an example, the electricity-generating coating 100 can include a conformal organic photovoltaic device configured to be applied and conformed to the surface of the cargo carrying vehicle 10 by coating the conformal organic photovoltaic device onto the surface of the cargo carrying vehicle 10. In another example, the electricity-generating coating 100 can include a pressure-sensitive adhesive on the conformal organic photovoltaic device, wherein the conformal organic photovoltaic device is configured to be applied and conformed to the surface of the cargo carrying vehicle 10 by adhering and conforming the pressure-sensitive adhesive of the conformal organic photovoltaic device onto the surface of the cargo carrying vehicle 10.

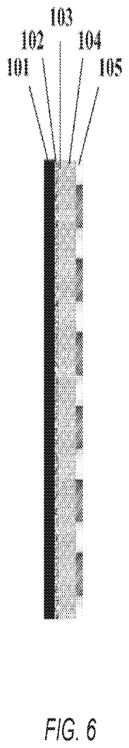

With reference to FIGS. 6-15, exemplary embodiments of an electricity-generating coating 100 for a cargo carrying vehicle 10 will now be described. Similar reference numerals are used for similar features of the exemplary embodiments.

FIG. 6 provides a cross-sectional view of an intermediate film stack produced for the eventual fabrication of electricity-generating coatings for surfaces of a cargo carrying vehicle 10. The exemplary film is prepared upon a temporary base layer 101, in order to provide sufficient rigidity to allow conventional manufacturing techniques, including high-speed roll-to-roll coating. The base layer 101 can include of thick polymer foils, metal foils, glass substrates, or any convenient substrate material, depending on the chosen manufacturing methods. On top of the base layer 101 is a transfer release layer 102 that allows easy removal of the base layer 101 and transfer release layer 102 from the thin flexible substrate 103, which are all laminated together as known to those skilled in the art. The thin flexible substrate 103 is any appropriate substrate material that is highly flexible and transparent, such as very thin polymer foils, including but not limited to polyethyleneterephthalate (PET). On top of the thin flexible substrate 103 is coated an electricity-generating coating device 104, comprising one or more cells connected in series and/or parallel, which is inherently flexible and thus contains no highly crystalline materials. The multi-layered electricity-generating coating device 104 is coated and processed according to standard methods known to those skilled in the art, such as slot-die coating and laser scribing, which are compatible with high-throughput manufacturing techniques, including high-speed roll-to-roll or sheet-to-sheet production methods. Finally, the electricity-generating coating device 104 is coated on top (on an exterior facing side when adhered to a surface of the vehicle 10) with a semitransparent pressure-sensitive adhesive 105 according to methods know to those skilled in the art. The resulting film comprising layers 101-105 can be used to transfer the electricity-generating coating device comprising layers 103-105 onto a surface of the cargo carrying vehicle 10 to the surface into an electricity-generating surface.

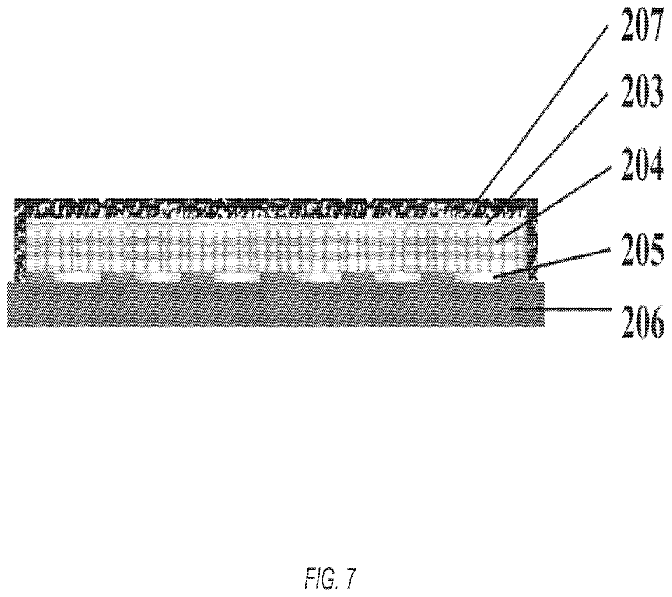

Referring to FIG. 7, which provides a cross-sectional view of a planar surface 206 of a cargo carrying vehicle 10 having an electricity-generating coating 100 produced via a pressure-sensitive adhesive method. In this example, a base layer 206 includes a planar surface of the cargo carrying vehicle 10. The electricity-generating device 204 is laminated onto the planar surface 206 of the cargo carrying vehicle 10 using stretching and press-forming, with or without vacuum assistance in removing entrained air. The electricity-generating coating device 204 is adhered to the planar surface 206 of the cargo carrying vehicle 10 using a pressure-sensitive adhesive layer 205, and is supported by the thin flexible substrate layer 203. Finally, the whole device 204 can be protected via a clear hard-coat 207 (e.g., a clear epoxy), which can be applied via a variety of techniques known to those skilled in the art, such as spray coating. While, in this exemplary embodiment, the method is necessarily a discrete object process for the fabrication of each individual surface 206 of the cargo carrying vehicle 10, the intermediate transfer film (see FIG. 6) used to transfer the completed electricity-generating coating device onto the planar surface 206 of the cargo carrying vehicle 10 can be produced in a continuous, high-throughput methodology. Not shown are any wires or other electrical contacts, or any power circuitry (e.g., inverters), which would be contained largely within the tractor 20 or trailer 50 of the cargo carrying vehicle 10.

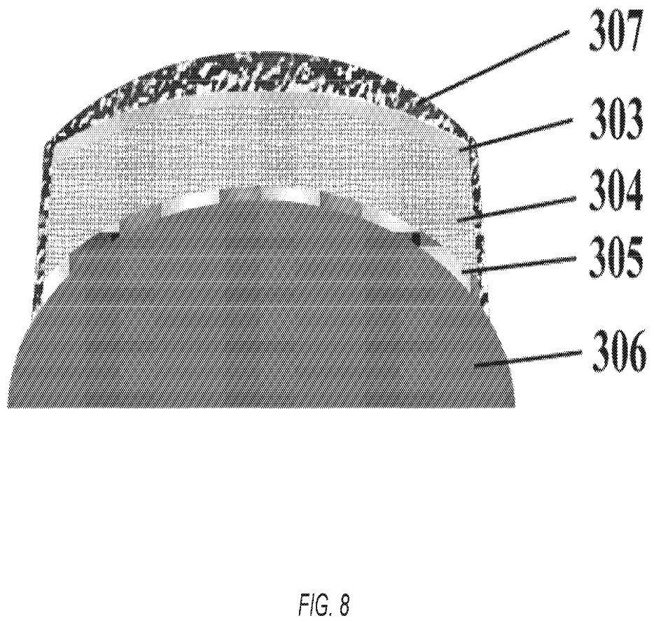

Referring to FIG. 8, which provides a cross-sectional view of a curved surface 306 of the cargo carrying vehicle 10 having an electricity-generating coating 100 produced via a pressure-sensitive adhesive method. The base layer 306 includes a curved surface 306 of a cargo carrying vehicle 10. The electricity-generating coating device 304 is laminated onto the curved surface 306 of the cargo carrying vehicle 10 using stretching and press-forming, with or without vacuum assistance in removing entrained air. The electricity-generating coating device 304 can be adhered to the curved surface 306 of the cargo carrying vehicle 10 using the pressure-sensitive adhesive layer 305, and is supported by the thin flexible substrate layer 303. Finally, the whole electricity-generating coating device 304 is protected via a clear hard-coat 307 (e.g., a clear epoxy), which can be applied via a variety of techniques known to those skilled in the art, such as spray coating. The unique and inherent flexibility of electricity-generating coating devices 100 allows lamination onto curved surfaces 306 of the cargo carrying vehicle 10 while minimizing or reducing disruption of device performance, and enables production of an electricity-generating coating device 100 that can be applied to cover or conform to a topography of all or a portion of various surfaces, with a variety of topographies, of a cargo carrying vehicle 10, which may be difficult to achieve via conventional coating techniques. For example, the exemplary devices and methods can enable electricity-generating coating devices 100 to be laminated onto curved surface 306 of the cargo carrying vehicle 10 of arbitrary and changing curvature (e.g., arbitrary or changing topography). While, in this exemplary embodiment, the method may be a discrete object process for the fabrication of each individual surface 306 of the cargo carrying vehicle 10, the intermediate transfer film (see FIG. 6) used to transfer the completed electricity-generating coating device 100 onto the curved surface 306 of the cargo carrying vehicle 10 can be produced in a continuous, high-throughput methodology. Not shown are any wires or other electrical contacts, or any power circuitry (e.g. inverters), which would be contained largely within the cargo carrying vehicle 10.

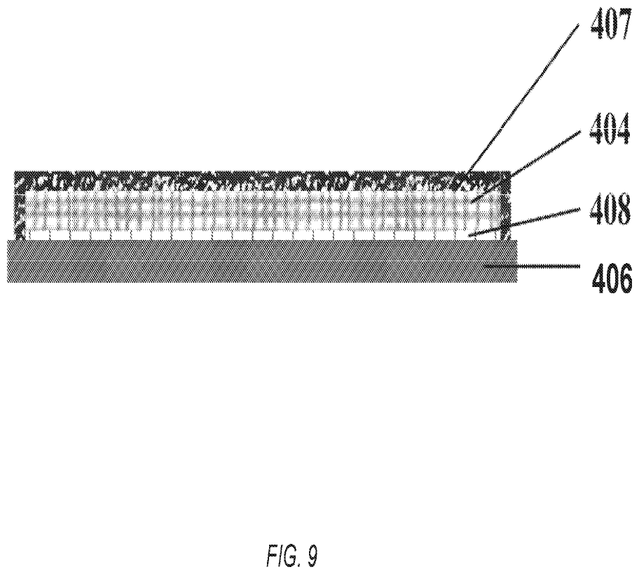

Referring to FIG. 9, which provides a cross-sectional view of a planar surface 406 of the cargo carrying vehicle 10 having an electricity-generating coating 100 produced via the conventional coating method, the base layer includes a planar surface 406 of the cargo carrying vehicle 10. First, the planar surface 406 of the cargo carrying vehicle 10 is coated with an insulating layer 408 using methods known to those skilled in the art, to allow isolation of the individual cells from each other and from the surface 406 of the cargo carrying vehicle 10, preventing electrification of the entire surface 406 or other components of the cargo carrying vehicle 10. The electricity-generating coating device 404 is then coated onto the insulating layer 408 using conventional coating techniques such as known to those skilled in the art. Finally, the whole electricity-generating coating device 404, 408 is protected via a clear hard-coat 407 (e.g., a clear epoxy), which can be applied via a variety of techniques known to those skilled in the art, such as spray coating. While this method has the advantage of having less extraneous layers and materials involved as compared to the laminated processes (see FIG. 7), in this exemplary embodiment, the method can include a sheet-to-sheet coating process performed on a surface-by-surface basis for every individual layer in the electricity-generating coating device, which can limit throughput and increase defects, compared to producing the electricity-generating coating device in a continuous process (see FIG. 6). Not shown are any wires or other electrical contacts, or any power circuitry (e.g. inverters), which would be contained largely within the cargo carrying vehicle 10.

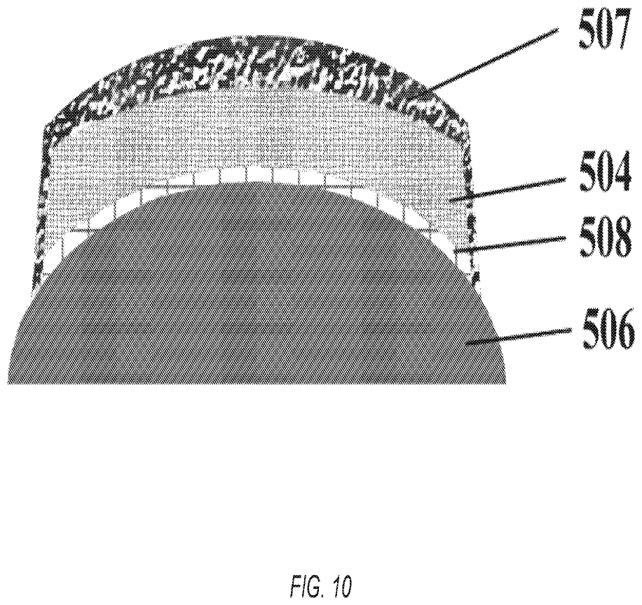

Referring to FIG. 10, which provides a cross-sectional view of a curved surface 506 of the cargo carrying vehicle 10 having an electricity-generating coating 100 produced via the conventional coating method, the base layer includes a curved surface 506 of the cargo carrying vehicle 10. First, the curved surface 506 of the cargo carrying vehicle 10 is coated with an insulating layer 508 using methods known to those skilled in the art, to allow isolation of the individual cells from each other and from the curved surface 506 of the cargo carrying vehicle 10, preventing electrification of the entire curved surface 506 or other components of the cargo carrying vehicle 10. The electricity-generating coating device 504 is then coated onto the insulating layer 508 using conventional coating techniques such as spray or curtain coating. Finally, the whole electricity-generating coating device 504, 508 is protected via a clear hard-coat 507 (e.g., a clear epoxy), which can be applied via a variety of techniques known to those skilled in the art, such as spray coating. As such, the pressure-sensitive adhesive lamination method presents an attractive alternative for the production of curved surfaces 506 of a cargo carrying vehicle 10 (see FIG. 8).

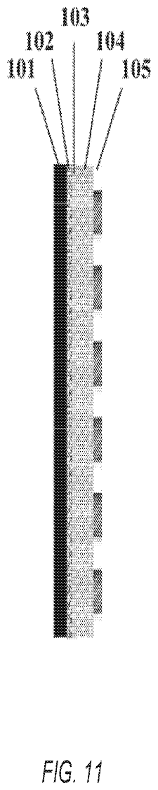

Referring now to the drawings, FIGS. 11-15 illustrate exemplary embodiments of electricity-generating coatings for a window surface and methods for manufacture thereof.

Referring to FIG. 11, which provides a cross-sectional view of an intermediate film stack produced for the eventual fabrication of electricity-generating coatings for window surfaces of a cargo carrying vehicle 10, the film or coating is prepared upon a temporary base layer 101, in order to provide sufficient rigidity to allow conventional manufacturing techniques, including high-speed roll-to-roll coating. The base layer 101 can include thick polymer foils, metal foils, or any convenient substrate material, depending on the chosen manufacturing methods. On top of the base layer 101 s a transfer release layer 102 that allows easy removal of the base layer 101 and transfer layer 102 from the thin flexible substrate 103, which are all laminated together as known to those skilled in the art.

The thin flexible substrate 103 is any appropriate substrate material that is highly flexible and transparent, such as very thin polymer foils, including but not limited to polyethyleneterephthalate (PET). On top of the thin flexible substrate 103 is coated a semi-transparent electricity-generating coating device 104, comprising one or more cells connected in series and/or parallel, which is inherently flexible and thus contains no highly crystalline materials. The multi-layered electricity-generating coating device 104 is coated and processed according to standard methods known to those skilled in the art, such as slot-die coating and laser scribing, which are compatible with high-throughput manufacturing techniques, including high-speed roll-to-roll or sheet-to-sheet production methods. Finally, the electricity-generating coating device 104 is coated on top with a semitransparent pressure-sensitive adhesive 105 according to methods know to those skilled in the art. The resulting film comprising layers 101-105 can be used to transfer the semitransparent electricity-generating coating device comprising layers 103-105 onto a window surface of a cargo carrying vehicle 10 to convert the window into electricity-generating window surface.

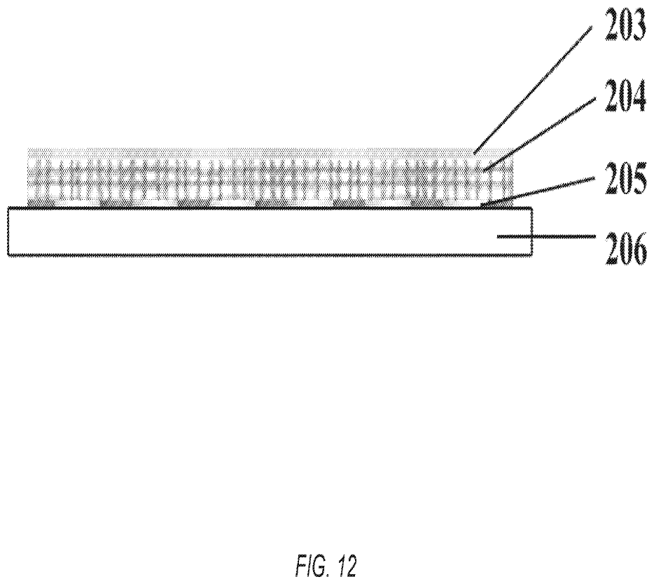

Referring to FIG. 12, which provides a cross-sectional view of a planar window surface of a cargo carrying vehicle 10 having an electricity generating coating 100 produced via the pressure-sensitive adhesive method, the base layer 206 comprises a planar window of a cargo carrying vehicle 10. The electricity-generating semitransparent electricity-generating coating device 204 is laminated onto the window 206 using stretching and press-forming, with or without vacuum assistance in removing entrained air. The electricity-generating semitransparent electricity-generating coating device 204, which is adhered to the window using the pressure-sensitive adhesive layer 205, and is supported by the thin flexible substrate layer 203. While, in this exemplary embodiment, the method is necessarily a discrete object process for the fabrication of each individual window, the intermediate transfer film (see FIG. 11) used to transfer the completed electricity-generating coating device onto the window can be produced in a continuous, high-throughput methodology. Not shown are any wires or other electrical contacts, or any power circuitry (e.g. inverters), which would be contained within the window casing or body of the cargo carrying vehicle 10, respectively, or any protective coatings that might be desirable.

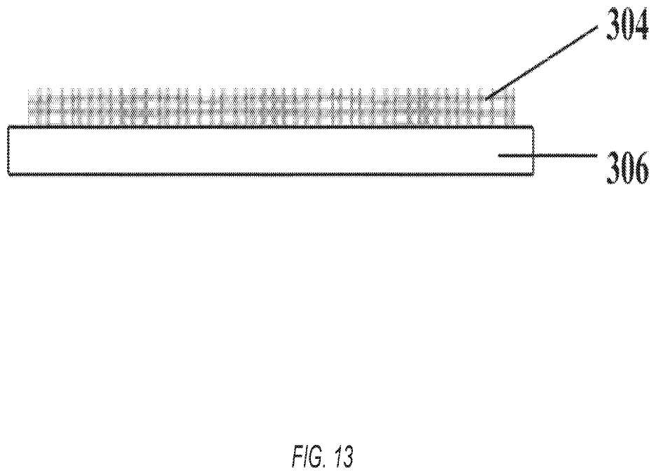

Referring to FIG. 13, which provides a cross-sectional view of a planar window of a cargo carrying vehicle 10, an electricity-generating coating 100 produced via the conventional coating method, the base layer 306 includes a planar window of a cargo carrying vehicle 10. The semitransparent electricity-generating coating device 304 is coated directly onto the window surface using conventional coating techniques such as known to those skilled in the art. While this method has the advantage of having less extraneous layers and materials involved as compared to the laminated processes (see FIG. 12), in this exemplary embodiment, it is necessarily a sheet-to-sheet coating process performed on a window-by-window basis for every individual layer in the electricity-generating coating device, which can limit throughput and increase defects, compared to producing the electricity-generating coating device in a continuous process (see FIG. 1). Not shown are any wires or other electrical contacts, or any power circuitry (e.g. inverters), which would be contained within the window casing or body of the cargo carrying vehicle 10, respectively, or any protective coatings that might be desirable. In the example shown in FIG. 13, the whole electricity-generating coating device 304 can be protected via a clear hard-coat (e.g., a clear epoxy), which can be applied via a variety of techniques known to those skilled in the art, such as spray coating.

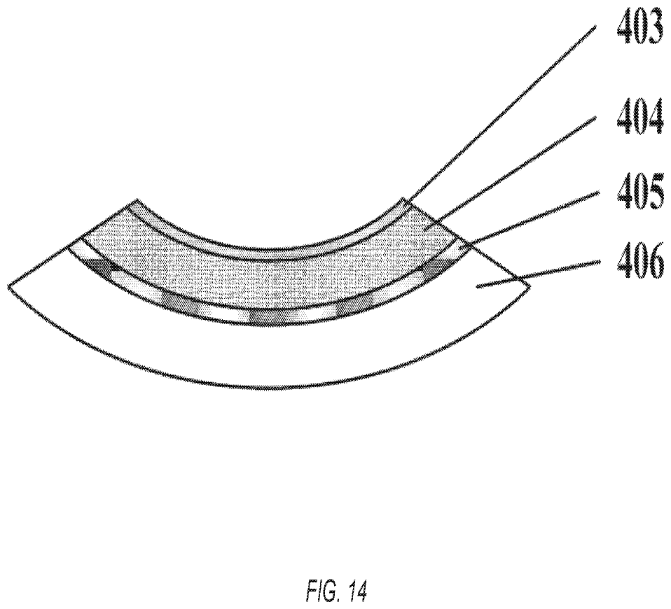

Referring to FIG. 14, which provides a cross-sectional view of a curved window 406 of a cargo carrying vehicle 10, an electricity-generating coating 100 produced via the pressure-sensitive adhesive method, the base layer 406 comprises a curved window 406 of a cargo carrying vehicle 10. The electricity-generating semitransparent electricity-generating coating device 404 is laminated onto the curved window 406 of a cargo carrying vehicle 10 using stretching and press-forming, with or without vacuum assistance in removing entrained air, is the electricity-generating semitransparent electricity-generating coating device 404, which is adhered to the window using the pressure-sensitive adhesive layer 405, and is supported by the thin flexible substrate layer 403. The unique and inherent flexibility of electricity-generating coating devices allows lamination onto curved surfaces (e.g., curved topography) without significant disruption of device performance, and enables production of electricity-generating coating devices applied and conformed to various topographies of surfaces of a cargo carrying vehicle that would be difficult to produce via conventional coating techniques due to realities of capillarity flow on curved surfaces. For example, the exemplary devices and methods enable electricity-generating coating devices to be laminated onto a curved window 406 of a cargo carrying vehicle 10 of arbitrary and changing curvature (e.g., varying topography, including planar, curved, or combinations thereof). While, in this exemplary embodiment, the method is necessarily a discrete object process for the fabrication of each individual window, the intermediate transfer film (see FIG. 11) used to transfer the completed electricity-generating coating device onto the window can be produced in a continuous, high-throughput methodology. Not shown are any wires or other electrical contacts, or any power circuitry (e.g., inverters), which would be contained within the window casing or body of a cargo carrying vehicle 10, respectively, or any protective coatings that might be desirable. In the example shown in FIG. 14, the whole electricity-generating coating device can be protected via a clear hard-coat (e.g., a clear epoxy), which can be applied via a variety of techniques known to those skilled in the art, such as spray coating.

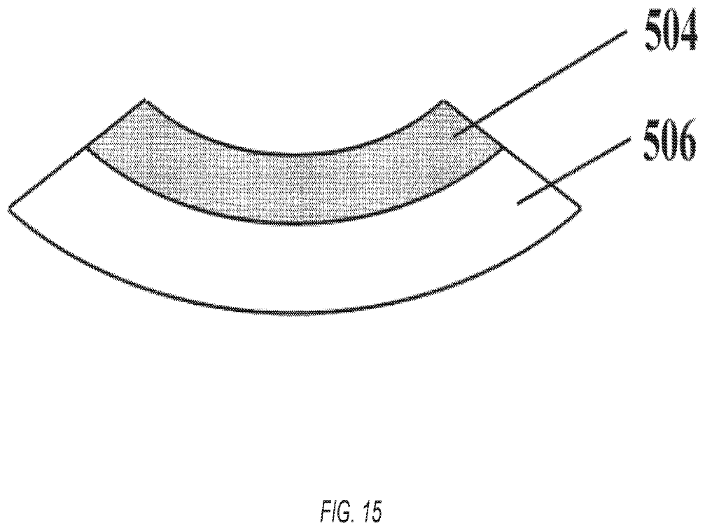

Referring to FIG. 15, which provides a cross-sectional view of a curved window 406 of a cargo carrying vehicle 10, the electricity generating coating 100 produced via the conventional coating method. The semitransparent electricity-generating coating device 504 is coated directly onto the window surface using conventional coating techniques such as spray or curtain coating. As such, the pressure-sensitive adhesive lamination method presents an attractive alternative for the production of curved window 406 of a cargo carrying vehicle 10 (see FIG. 14). In the example shown in FIG. 15, the whole electricity-generating coating device can be protected via a clear hard-coat (e.g., a clear epoxy), which can be applied via a variety of techniques known to those skilled in the art, such as spray coating.

The present invention has been described herein in terms of several preferred embodiments. However, modifications and additions to these embodiments will become apparent to those of ordinary skill in the art upon a reading of the foregoing description. It is intended that all such modifications and additions comprise a part of the present invention to the extent that they fall within the scope of the several claims appended hereto.

1. A cargo carrying vehicle designed to transport cargo on land to a destination, the cargo carrying vehicle comprising:
an electrical system having one or more electrical components;
a surface having an electricity-generating film coupled thereto, the electricity generating film comprising;
a stack of layers for converting light into electrical energy, the stack of layers comprising a conformal organic photovoltaic device configured to convert light incident to the surface into electrical current, the stack of layers including at least one conducting layer configured to collect and transfer at least some of the electrical current to the electrical system,
wherein the stack of layers is configured to be flexible to allow the film to conform to the surface so that the surface is aerodynamic, and
wherein the stack of layers is configured to be transparent or semitransparent so as to allow at least a portion of the light incident to the surface to pass through the film.

2. The cargo carrying vehicle of claim 1, wherein the electricity-generating film is applied and conformed to the surface by coating the stack of layers onto the surface.

3. The cargo carrying vehicle of claim 2, wherein the electricity-generating film is coated directly onto the surface.

4. The cargo carrying vehicle of claim 3, wherein the electricity-generating film is coated directly onto the surface such that a topography of the electricity-generating film conforms to a topography of the surface.

5. The cargo carrying vehicle of claim 4, wherein the electricity-generating film is coated directly onto the surface without any space or entrapped air being present between the electricity-generating film and the surface such that the topography of the electricity-generating film directly conforms to the topography of the surface.

6. The cargo carrying vehicle of claim 1, wherein the electricity-generating film further comprises:
a pressure-sensitive adhesive on the stack of layers, wherein the electricity-generating film is configured to be applied and conformed to the surface by adhering and conforming the pressure-sensitive adhesive onto the surface.

7. The cargo carrying vehicle of claim 6, wherein the pressure-sensitive adhesive is configured to be adhered and conformed directly onto the surface.

8. The cargo carrying vehicle of claim 6, wherein the pressure-sensitive adhesive is configured to be adhered and conformed directly onto the surface such that a topography of the electricity-generating film conforms to a topography of the surface.

9. The cargo carrying vehicle of claim 8, wherein the pressure-sensitive adhesive is configured to be adhered and conformed directly onto the surface without any space or entrapped air being present between the pressure-sensitive adhesive and the surface such that the topography of the electricity-generating film directly conforms to the topography of the surface.

10. The cargo carrying vehicle of claim 1, wherein a topography of the surface includes at least one planar surface.

11. The cargo carrying vehicle of claim 1, wherein a topography of the surface includes at least one curved surface.

12. The cargo carrying vehicle of claim 1, wherein a topography of the surface includes a combination of at least one planar surface and at least one curved surface.

13. The cargo carrying vehicle of claim 1, wherein the surface is a non-transparent surface.

14. The cargo carrying vehicle of claim 1, wherein the surface is one of a transparent surface and a semi-transparent surface.

15. (canceled)

16. The cargo carrying vehicle of claim 6, wherein the surface is one of a transparent surface and a semi-transparent surface, and wherein the electricity-generating film is configured such that at least a portion of the light incident to the surface is capable of passing through the stack of layers and the pressure-sensitive adhesive.

17. (canceled)

18. The cargo carrying vehicle of claim 6, wherein the stack of layers is flexible and the pressure-sensitive adhesive is flexible.

19. The cargo carrying vehicle of claim 1, wherein the surface is an exterior surface of a component of the cargo carrying vehicle.

20. The cargo carrying vehicle of claim 1, wherein the surface is an interior surface of a component of the cargo carrying vehicle.

21. The cargo carrying vehicle of claim 1, wherein the electricity-generating coating is configured to supply power for the one or more electrical components of the electrical system.

22. The cargo carrying vehicle of claim 19, wherein a leading edge of the electricity-generating film is concealed behind a second exterior surface of the cargo carrying vehicle.
